(19) United States
(12) Patent Application Publication
(10) Pub. No.: US 2024/0347231 A1
(43) Pub. Date: Oct. 17, 2024

(54) METHOD FOR PRODUCING SHAPED PARTS FROM AN ELECTRICALLY CONDUCTIVE PLANAR ELEMENT AND CIRCUIT BOARD HAVING ATLEAST ONE SHAPED PART OF THIS TYPE

(71) Applicant: JUMATECH GMBH, Eckental (DE)

(72) Inventor: Markus WÖLFEL, Eckental (DE)

(21) Appl. No.: 18/683,471

(22) PCT Filed: Jul. 21, 2022
(86) PCT No.: PCT/EP2022/070501

§ 371 Date: Feb. 13, 2024

(30) Foreign Application Priority Data
Aug. 16, 2021 (DE) 10 2021 121 249.9

(51) Int. Cl. H01B 13/00; H05K 1/11; H05K 1/18

(52) U.S. Cl. CPC H01B 13/0036; H05K 1/11; H05K 1/182

(57) ABSTRACT

A method is provided for producing shaped parts from an electrically conductive planar element, wherein, for the contouring of at least one shaped part, the electrically conductive planar element is completely cut through along first contour lines, in order to at least partly expose the shaped part. In order to facilitate the further processing of the shaped part, the thickness of the electrically conductive planar element is reduced along second contour lines, so that the shaped part remains connected only along the second contour lines by means of material bridges and can be detached as a result of these material bridges being cut through. A circuit board having at least one shaped part of this type is also provided.

### CROSS REFERENCE TO RELATED APPLICATIONS

This application is a U.S. National Phase Application under 35 U.S.C. 371 of International Application No. PCT/EP2022/070501, filed on Jul. 21, 2022, which claims priority to German Patent Application No. 10 2021 121 249.9, filed on Aug. 16, 2021. The entire disclosures of the above applications are expressly incorporated by reference herein.

### BACKGROUND

### Technical Field

The present invention relates to a method for producing shaped parts from an electrically conductive planar element and to a circuit board with at least one shaped part of this type.

### Related Art

In a known method for producing shaped parts for circuit boards from an electrically conductive planar element, the contours of the shaped parts are partly exposed, so that the shaped parts only remain connected to each other or to the electrically conductive planar element at isolated material bridges and can then be detached from each other and from the electrically conductive planar element by cutting through these material bridges.

A corresponding method is disclosed in DE 10 2020 145 140.8 (as yet unpublished), among others. Shaped parts for circuit boards are known from DE 10 2011 102 484, among others.

However, when these material bridges are cut through, the shaped parts may not be cleanly separated from each other, so that the contours of the cut out shaped parts are blurred at the breaking points of the former material bridges and may have to be reworked, especially if the shaped parts are positioned in molds for the production of circuit boards based on their outer contour.

The underlying problem of the present invention is to improve a method for producing shaped parts from an electrically conductive planar element in such a way that further processing of the shaped parts for circuit board production is facilitated.

### SUMMARY

In order to solve the problem, the invention provides the method for producing shaped parts from an electrically conductive planar element, wherein the electrically conductive planar element for contouring at least one shaped part is completely cut through along first contour lines in order to partly expose the shaped part and is reduced in thickness along second contour lines so that the shaped part remains connected only along the second contour lines by means of material bridges and can be detached by cutting through these material bridges. The material bridges can exist between two shaped parts or between a shaped part and a part or edge of the electrically conductive planar element, which remains behind as material waste. According to the method known from the prior art, the contours of the shaped parts were only partly defined, wherein no contouring of the shaped parts took place at the material bridges as predetermined breaking points. In accordance with the method according to the invention, the contour of each shaped part to be cut out is completely defined by the first and second contour lines, i.e. around the entire circumference of the shaped part, in particular also at the material bridges to be cut through. By reducing its thickness along the second contour lines, the electrically conductive planar element is considerably weakened. Only a small amount of force is required to cut through the remaining material bridges. By contouring the shaped parts along the second contour lines, this force is concentrated precisely on the material bridges, for example when the shaped parts are cut out of the plane of the electrically conductive planar element along these material bridges. After contouring the shaped parts, however, the shaped parts are still connected by means of the material bridges and can be further processed in the composite, for example by removing the etch-resistant mask and/or applying an adhesion promoter layer. After processing in the composite, the individual shaped parts can then be separated and removed from the composite.

Preferred embodiments of the invention are also provided.

It can be preferred if the shaped parts are contoured along the first and second contour lines using an etching process, wherein the electrically conductive planar element is preferably exposed to an etching substance, preferably sprayed with an etching substance. In principle, the shaped parts can be contoured using any technique, for example using a machining method or laser cutting. However, particularly complex contours can be produced comparatively easily and quickly using the etching process because the etching treatment can be carried out simultaneously at different points on the electrically conductive planar element.

It can prove to be helpful if the etching substance acts on the electrically conductive planar element along the first and second contour lines simultaneously and/or for the same length of time. This makes it easier to handle the electrically conductive planar element during the etching treatment. In principle, the etching substance eats its way through the thickness of the electrically conductive planar element as time progresses, starting from the side that is exposed to it. Consequently, the depth of an etched structure or the remaining material thickness/thickness of the electrically conductive planar element can be influenced by the exposure time of the etching substance. However, the depth of an etched structure does not depend exclusively on the exposure time of the etching substance, but also on other factors such as the length and width of the surface on which the etching substance acts and also on the etching substance itself, for example its aggressiveness or degree of saturation.

It can be useful if an etch-resistant mask is applied to the electrically conductive planar element to define the first and second contour lines, preferably on one or both sides of the electrically conductive planar element, so that some surface sections of the electrically conductive planar element are covered by the etch-resistant mask and other surface sections of the electrically conductive planar element are exposed to form the first and second contour lines. This mask is used to define the contours of the shaped parts or the first and second contour lines. The surface sections within these contour lines to be formed are covered by the mask and are therefore inaccessible to the etching substance during the etching treatment. Accordingly, no etching substance can act on the electrically conductive planar element at these covered surface sections.

It can prove to be practical if the exposed surface sections form a network of channels, in particular a branched one, with thicker and thinner channel sections running through the covered surface sections, wherein the thicker channel sections serve to form the first contour lines and the thinner channel sections serve to form the second contour lines. According to this variant, the etching rate at the exposed surface sections—and thus the penetration depth of the etching substance or the remaining material thickness of the electrically conductive planar element—is controlled via the width of the channel sections or via the distances between the covered surface sections. Especially with elongated channel sections of constant width, the penetration depth of the etching substance can be determined comparatively precisely via the channel width. In this respect, it is preferred that all first channel sections each have the same width and all second channel sections each have the same, smaller width than the first channel sections.

It may be useful if etch-resistant masks are applied to both sides of the electrically conductive planar element to form the first and second contour lines, wherein the masks are congruent or non-congruent on both sides of the electrically conductive planar element, wherein preferably, in the case of non-congruent masks on both sides of the electrically conductive planar element, some or all of the thicker channel sections for forming the first contour lines coincide or overlap at least partly and/or some or all of the thinner channel sections for forming the second contour lines are at least partly offset relative to one another, preferably running parallel to one another, so that the electrically conductive planar element is reduced in its thickness when the shaped parts are contoured, starting from both sides and forming second contour lines which are offset relative to one another, wherein preferably the minimum distance between the mutually offset second contour lines in the plane of the electrically conductive planar element is less than the overlap of the mutually offset second contour lines perpendicular to the plane of the electrically conductive planar element. In this variant, complex spatial structures can be created. In particular, the contour of a shaped part can be defined particularly precisely with this variant because the weakest part of a material bridge is located between two sections of the electrically conductive planar element that overlap in the thickness direction. Accordingly, the material bridge of a shaped part lies within its outer contour and is not visible in the top view of the shaped part.

It can prove useful if the contouring along the first and second contour lines produces a self-contained outer contour for each shaped part, preferably an identical outer contour for all shaped parts. In this way, the shaped part can be cut out of the electrically conductive planar element with little effort.

It can be preferred if all linear contours of the shaped parts, preferably the respective parallel longitudinal and transverse edges of the shaped parts, are exposed during the contouring of the shaped parts and all non-linear contours of the shaped parts remain connected to other shaped parts or an edge of the electrically conductive planar element by means of material bridges. As a result, the linear contours of these shaped parts are defined particularly precisely.

It may prove helpful if some or all of the first contour lines each extend partly or completely along a straight line and/or some or all of the second contour lines each extend partly or completely along a curved, in particular circular arc-shaped line, wherein preferably at least some of the second contour lines are self-contained.

It can be useful if each first contour line starts at a second contour line and ends at a second contour line. This allows the first and second contour lines to be defined precisely.

It can prove practical if some or all of the first and second contour lines meet at right angles. This allows the first and second contour lines to be separated from one another particularly precisely.

It can be useful if the shaped parts to be cut out are arranged in a matrix in rows and columns in the electrically conductive planar element, preferably with the same shape and/or orientation with respect to the outline of the electrically conductive planar element. This allows the largest possible number of shaped parts to be produced from one electrically conductive planar element.

It can prove useful if each shaped part has a polygonal, in particular rectangular, basic contour, preferably with concave rounded corners that run along the second contour lines and are preferably cut with convex rounded, in particular circular (section) shaped structures that form parts of the material bridges. This results in a comparatively stable composite even after contouring the shaped parts, which is easy to process but can still be easily separated by cutting through these material bridges.

It can be preferred if each shaped part is connected to at least one other shaped part by means of at least one material bridge, preferably to two, three or more than three other shaped parts. This minimizes the material waste of the electrically conductive planar element.

A further aspect of the present invention relates to a circuit board with at least one shaped part which is produced according to the method according to one of the preceding embodiments, wherein the shaped part is embedded at least partly in insulating material and is preferably electrically connected at connection points to a conductor structure of the circuit board, wherein the conductor structure of the circuit board preferably has etched strip conductors. The shaped parts produced according to the method of the invention can be used particularly well for the transmission of large amounts of current and/or heat within circuit boards.

Further preferred embodiments of the invention result from combinations of the features disclosed herein.

### BRIEF DESCRIPTION OF THE DRAWINGS

It is Shown by:

FIG. 1 is an electrically conductive planar element in rectangular form in top view.

FIG. 2 is the electrically conductive planar element of FIG. 1, which is exposed on its upper surface to an etch-resistant mask, wherein the mask comprises islands of covered surface sections within a network of thick and thin channels surrounding the islands, at which the surface of the electrically conductive planar element is accessible for etching treatment.

FIG. 3 is the electrically conductive planar element from FIG. 2 after the etching treatment, in which the electrically conductive planar element was completely cut along the thick channel sections and only reduced in thickness along the thin channel sections, so that the shaped parts remain connected to each other and to the edge of the electrically conductive planar element by means of material bridges.

FIG. 4 is a schematic partial view of a surface of the electrically conductive planar element with an etch-resistant mask for defining the contours and contour lines of the shaped parts to be cut out, wherein the shaped parts to be cut out are arranged in matrix form in rows and columns, wherein the concavely rounded corner regions of the shaped parts arranged in adjacent rows and columns are cut with a circular structure which is later retained as a material bridge.

FIG. 5 is an enlarged detail from FIG. 4 for illustrating the contours and contour lines of a single shaped part to be cut out, wherein the first contour lines extend along straight lines on the longitudinal and transverse sides of the essentially rectangular shaped part to be cut out, and the second contour lines extend approximately in the form of a quarter circle in the concavely rounded corner regions.

FIG. 6 is another enlarged detail from FIG. 4 for illustrating the contours and contour lines in the corner area of four shaped parts to be cut out.

FIG. 7a is a perspective photographic view of an electrically conductive planar element after an etching treatment, wherein the shaped parts arranged in rows and columns like a matrix are only connected at corner nodes by means of material bridges.

FIG. 7b is a perspective photographic view of the electrically conductive planar element from FIG. 4 after the mechanical separation of individual shaped parts by cutting the material bridges.

FIG. 8 is a perspective photographic view of a shaped part that has been separated by cutting the material bridges.

FIG. 9 is a computer-generated top view of a shaped part with material bridges connected in the four corners according to a second embodiment of the present invention.

FIG. 10 is a perspective, computer-generated view of a corner region of the shaped part of FIG. 9, wherein the shaped part was produced using an electrically conductive planar element which was exposed to different etch-resistant masks on both sides, so that the thickness of the electrically conductive planar element was reduced from both sides in the course of the etching process and as a result produces a meander-shaped material bridge in cross-section through the electrically conductive planar element, which has its thinnest point in a plane or direction parallel to the surfaces of the planar element or shaped part.

FIG. 11 is another perspective, computer-generated view of the corner region of the shaped part from FIGS. 9 and 10.

FIG. 12 is another computer-generated side view of the corner region of the shaped part from FIGS. 9 to 11.

### DETAILED DESCRIPTION

Preferred embodiments of the present invention are described in detail below with reference to the accompanying drawings.

The method described herein is used to produce shaped parts 1, in particular but not exclusively for circuit boards, from a planar element 2, in particular from an electrically conductive planar element 2.

Circuit boards are used, among other things, for the compact interconnection of electronic components with conductor structures provided on the circuit board. For the transmission of large amounts of current and heat, electrically conductive shaped parts 1 are used, which, in contrast to conductor wires, generally have a larger and non-uniform cross-sectional area. A method for producing shaped parts for circuit boards and a circuit board with corresponding shaped parts is known, for example, from DE 10 2011 102 484.

Shaped parts 1 of this type are made of metal, for example, in particular copper or copper alloys.

In order to produce such shaped parts 1 in large quantities and with high precision, several, usually identical shaped parts 1 are produced from a single electrically conductive planar element 2, as for example a copper plate. For certain purposes, in particular for connecting these shaped parts 1 to other components of the circuit board, it is usually desirable to be able to position these shaped parts 1 with particular precision in relation to these other components of the circuit board. The trend towards miniaturization of electrical components reinforces this desire.

In accordance with the method according to the invention, the electrically conductive planar element 2 for contouring the shaped parts 1 is completely cut along first, in particular straight contour lines 3 in order to partly expose the shaped parts 1. The electrically conductive planar element 2 is only reduced in thickness along second, for example circle section-shaped or circular contour lines 4. As a result, the shaped parts 1 only remain connected to each other or to the electrically conductive planar element 2 along the second contour lines 4 by means of material bridges 5. By cutting through these material bridges 5, the shaped parts 1 can be subsequently detached from each other or from the electrically conductive planar element 2.

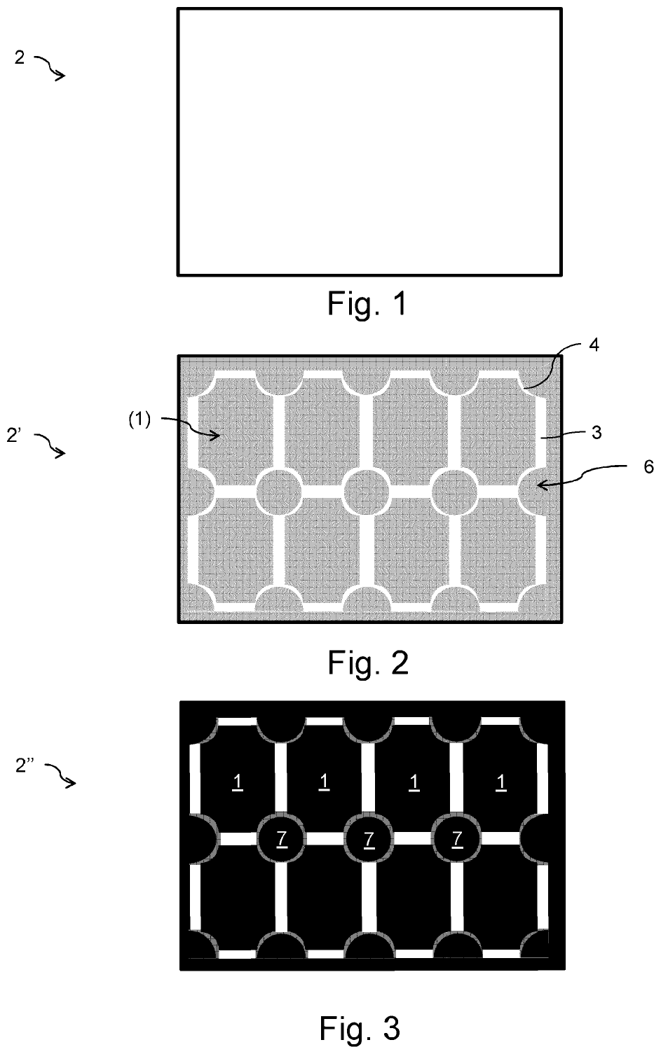

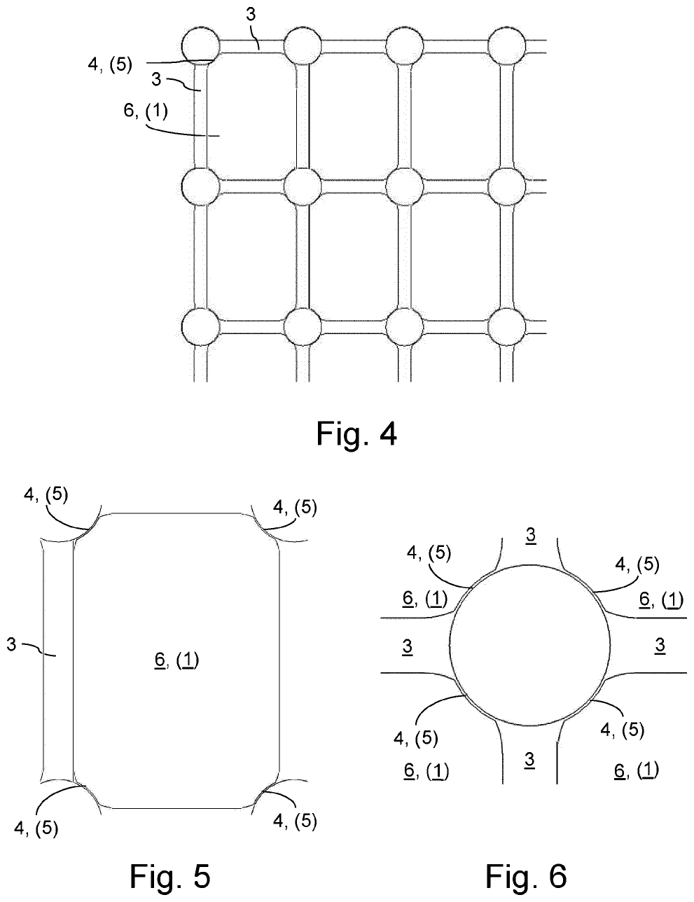

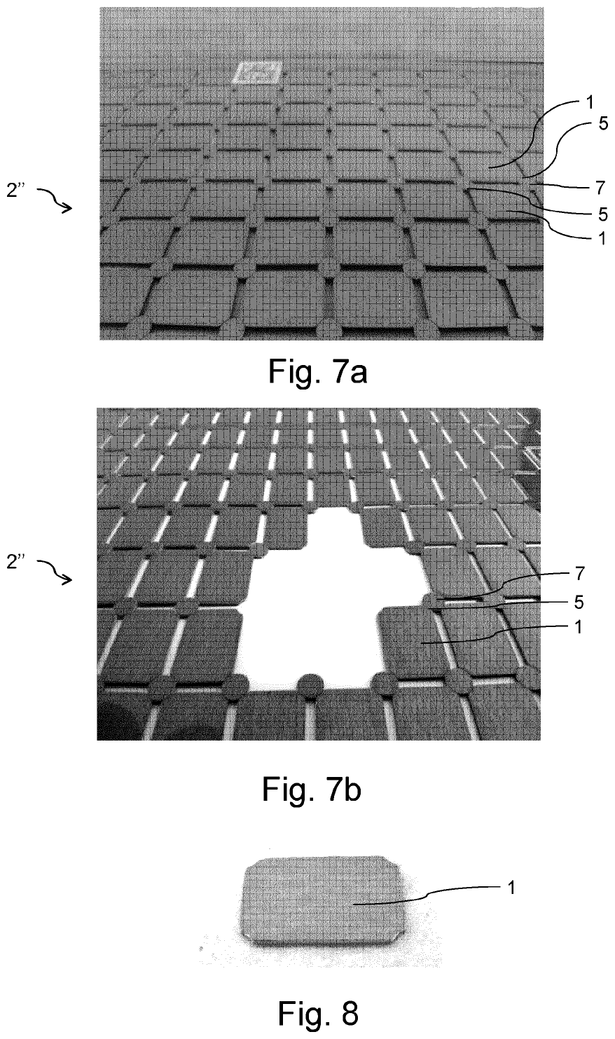

### First Embodiment (FIGS. 1-8)

According to the first embodiment of the invention, the contouring of the shaped parts 1 along the first and second contour lines 3, 4 is carried out using an etching process. In this process, the electrically conductive planar element 2, for example in the form of a metal plate, in particular a rectangular copper plate, is sprayed with an etching substance so that the etching substance acts simultaneously and for the same length of time on the electrically conductive planar element 2 along the first and second contour lines 3, 4.

In preparation for the etching treatment, an etch-resistant mask 6 is applied to the electrically conductive planar element 2 to define the first and second contour lines 3, 4.

A copper plate 2 with mask 6 applied to one side is shown in FIG. 2, for example. On the visible surface of this copper plate 2, some surface sections are covered by the etch-resistant mask 6, while other surface sections are exposed in between, which serve to form the first and second contour lines 3, 4.

These exposed surface sections form a branched network of channels with thicker and thinner channel sections running through the covered surface sections. The thicker channel sections are used to form the first contour lines 3 and the thinner channel sections are used to form the second contour lines 4.

In the course of the etching treatment, the copper plate 2 is completely cut along the thicker channel sections that form the first contour lines 3 and only reduced in thickness along the thinner channel sections that form the second contour lines 4. The contouring along the first and second contour lines 3, 4 creates the same, self-contained outer contour for each shaped part 1. In this way, all linear contours of the shaped parts 1, i.e. the respective parallel longitudinal and transverse edges of the shaped parts 1, are exposed. The circular section-shaped, concavely rounded corner regions of the shaped parts 1 remain connected to other shaped parts 1 or an edge of the electrically conductive planar element 2 by means of the material bridges 5.

All first contour lines 3 preferably begin and end at a second contour line 4 that is perpendicular to them.

After the etching treatment, the shaped parts 1 to be cut out are arranged in rows and columns in the electrically conductive planar element 2 in a matrix. Each shaped part 1 has a rectangular basic contour with concave rounded corners, which are cut along circular section-shaped structures forming parts of the material bridges 5.

Thus, each shaped part 1 is connected to the edge of the planar element 2 or at least one other shaped part 1 by means of at least one material bridge 5.

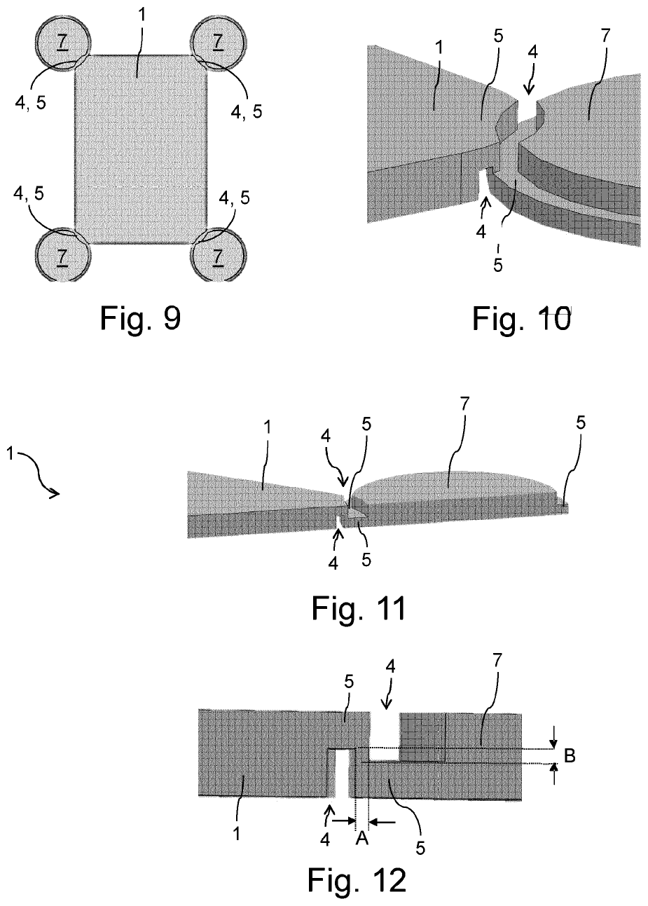

### Second Embodiment (FIGS. 9-12)

The second embodiment of the invention, which is described below with reference to FIGS. 9-12, is essentially based on the first embodiment. In order to avoid repetition, reference is made to the above description. Identical reference signs are used for identical features. The differences to the first embodiment are explained below.

According to the second embodiment of the invention, different etch-resistant masks 6 are applied to both sides of the electrically conductive planar element 2 to form the first and second contour lines 3, 4. The masks 6 applied to both sides of the electrically conductive planar element 2 are not congruent when viewed perpendicularly to the electrically conductive planar element 2.

In this viewing direction, only the thicker channel sections for forming the first contour lines 3 overlap each other or are congruent. In contrast, at least some of the thinner channel sections for forming the second contour lines 4 are at least partly offset parallel to each other.

When contouring the shaped parts 1, the electrically conductive planar element 2 is sprayed with an etching liquid as part of the etching treatment and completely cut along the first contour lines 1. Starting from both sides with the formation of mutually offset second contour lines 4, the electrically conductive planar element 2 is only reduced in thickness along the thinner channel sections. As shown in FIGS. 10-12 and in particular FIG. 12, the resulting second contour lines 4 are slightly offset parallel to each other. As shown in FIG. 12, the minimum distance A of these second contour lines 4 in the plane of the electrically conductive planar element 2 is smaller than the overlap B of the mutually offset second contour lines 4 perpendicular to the plane of the electrically conductive planar element 2. In a top view of the surface of the shaped part 1, the contour of the shaped part 1 is retained even after these material bridges 5 have been cut through, since the material bridges 5 or the weakest material cross-sections lie completely within the outer contour of these shaped parts 1. Thus, if necessary, no further reworking of the outer contour of the shaped parts 1 is required after these material bridges 5 have been cut through.

A circuit board according to the invention comprises at least one shaped part 1 which is produced according to the method according to the invention. In this case, the shaped part 1 is at least partly embedded in insulating material and electrically connected to a conductor structure of the circuit board. The conductor structure of the circuit board comprises etched strip conductors. A similar circuit board is known from DE 10 2011 102 484 A1.

In other words, the advantages of the present invention embodiments can be paraphrased as follows:

The basic idea of the present embodiments is to make the shaped parts 1 or molds separable by varying the etching rate.

After etching, an electrically conductive planar element 2 is to be obtained in the form of a metal or copper plate 2 with shaped parts 1 or molds that are still connected, however easily separable. As a result, a multi-stage etching process (pre-etching with vacuum and through-etching) can be omitted and the copper plate 2 does not need to be handled between the etching processes. The handling of the copper plate 2 and the shaped parts 1 is simplified overall. The positional stability of the shaped parts 1 is maintained until they are separated, and blurring of the already positioned shaped parts 1 can be prevented.

The etching treatment of the copper plate 2 results in a homogeneous etching pattern because there is no blurring of the shaped parts 1.

The etching rate depends, among other things, on the exchange of the surface of the electrically conductive planar element 2 with the etching liquid. This is minimized in particularly narrow and deep channels or contours, which form the second contour lines 4, and the removal rate is reduced as a result. This effect should be used to leave thin webs along the second contour lines 4 as material bridges 5 or “holders” after the etching process, which can be separated automatically with little force and without a large overhang.

A circle was chosen as the contour for these material bridges 5, which is cut into an outer edge or outer contour of the shaped parts 1 such that a possible overhang would not interfere.

Within the scope of protection of the claims, any modifications of these embodiments are possible.

1-15. (canceled)

16. A method for producing at least one shaped part from an electrically conductive planar element, comprising:
completely cutting through the electrically conductive planar element along first contour lines in order to at least partly expose the shaped part; and
reducing a thickness along second contour lines, so that the shaped part remains connected only along the second contour lines by material bridges and is detachable by cutting through the material bridges.

17. The method according to claim 16, further comprising:
contouring the shaped part along the first and second contour lines by an etching process.

18. The method according to claim 17, wherein an etching substance of the etching process acts along the first and second contour lines simultaneously and/or for the same length of time on the electrically conductive planar element.

19. The method according to claim 17, wherein an etch-resistant mask is applied to the electrically conductive planar element to define the first and second contour lines, so that some surface sections of the electrically conductive planar element are covered by the etch-resistant mask and other surface sections of the electrically conductive planar element are exposed to form the first and second contour lines.

20. The method according to claim 19, wherein the exposed surface sections form a branched channel network with thicker and thinner channel sections passing through the covered surface sections, wherein the thicker channel sections form the first contour lines and the thinner channel sections form the second contour lines.

21. The method according to claim 19, wherein etch-resistant masks are applied to both sides of the electrically conductive planar element to form the first and second contour lines, wherein the masks are congruent or non-congruent on both sides of the electrically conductive planar element, wherein in the case of non-congruent masks on both sides of the electrically conductive planar element, some or all of thicker channel sections for forming the first contour lines overlap one another and/or some or all of thinner channel sections for forming the second contour lines are at least partly offset relative to one another, so that the electrically conductive planar element is reduced in thickness when the shaped parts are contoured, starting from both sides and forming the second contour lines offset from one another, wherein a minimum distance of the mutually offset second contour lines in the plane of the electrically conductive planar element is less than the overlap of the mutually offset second contour lines perpendicular to the plane of the electrically conductive planar element.

22. The method according to claim 19, wherein the contouring along the first and second contour lines produces a self-contained outer contour for the shaped part.

23. The method according to claim 19, wherein during the contouring of the shaped part all linear contours of the shaped part are exposed and all non-linear contours of the shaped part remain connected to further shaped parts or an edge of the electrically conductive planar element by material bridges.

24. The method according to claim 19, wherein some or all of the first contour lines each extend partly or completely along a straight line and/or some or all of the second contour lines each extend partly or completely along a curved line.

25. The method according to claim 19, wherein each first contour line begins at a second contour line and ends at a second contour line.

26. The method according to claim 19, wherein some or all of the first and second contour lines meet at right angles.

27. The method according to claim 19, wherein the shaped part to be cut out is arranged with further shaped parts to be cut in a matrix form in rows and columns in the electrically conductive planar element.

28. The method according to claim 19, wherein the shaped part has a polygonal basic contour with concavely rounded corners which run along the second contour lines and are cut with convexly rounded structures which form parts of the material bridges.

29. The method according to claim 19, wherein the shaped part is connected by at least one material bridge to at least one other shaped part.

30. A circuit board having at least one shaped part which is produced by the method according to claim 19, wherein the shaped part is at least partly embedded in insulating material and is electrically connected at connection points to a conductor structure of the circuit board, wherein the conductor structure of the circuit board has etched strip conductors.

31. The method according to claim 17, wherein the etching process further comprises spraying with an etching substance.
